(19) United States
(12) Patent Application Publication
(10) Pub. No.: US 2007/0166935 A1
(43) Pub. Date: Jul. 19, 2007

(54) Method of fabricating nonvolatile memory device

(75) Inventor: Chul Jin Yoon, Suwon-si (KR)

Correspondence Address: THE LAW OFFICES OF ANDREW D. FORTNEY, PH.D., P.C., 401 W FALLBROOK AVE STE 204, FRESNO, CA, 93711-5835, US

(73) Assignee: Dongbu Electronics Co., Ltd.

(21) Appl. No.: 11/647,864

(22) Filed: Dec. 28, 2006

(30) Foreign Application Priority Data
Dec. 28, 2005 (KR) 10-2005-0132661

(51) Int. Cl. H01L 21/336

(52) U.S. Cl. 438/296

(57) ABSTRACT

Provided is a method of fabricating a nonvolatile memory device. According to the method, in a semiconductor substrate where a cell region and a logic region are defined, an isolation region and an active region are defined in each of the cell region and the logic region, and a low voltage region and a high voltage region are defined in the logic region, a shallow trench isolation region is formed in the isolation region. A first gate insulating layer and a first gate electrode are formed in one region of the cell region. Second and third gate insulating layers are formed in respective regions of the logic region. A semiconductor layer is deposited on an entire surface of the semiconductor substrate. The semiconductor layer is etched to form a second gate electrode to overlap a portion of the first gate electrode. An entire surface of the semiconductor substrate is coated with a bottom antireflection coating layer. The semiconductor layer is etched to form third and fourth gate electrodes in respective regions of the logic region.

### BACKGROUND OF THE INVENTION

1. Field of the Invention

The present invention relates to a method of fabricating a nonvolatile memory device.

2. Description of the Related Art

A nonvolatile memory has an advantage of maintaining stored data even when power supply is stopped, and thus has been used as a data storage of a personal computer basic integrated operating system (PC BIOS), a set-top box, a printer, a network server, etc. The nonvolatile memory has been recently used for a digital camera, a cellular phone, etc.

In particular, an electrically erasable programmable read only memory (EEPROM) of the nonvolatile memory device electrically erases data of a memory cell entirely or in sector units, and includes a flash memory device. In a program operation of the flash memory device, channel hot electrons are formed in a drain and are accumulated in a floating gate, thereby increasing a threshold voltage of a cell transistor. On the other hand, in an erase operation of the flash memory device, a high voltage is applied between a source/substrate and the floating gate to emit the electrons accumulated in the floating gate, thereby decreasing a threshold voltage of a cell transistor.

Recently, a high integration of a device requires reducing a cell size. However, there is a limit in reducing the cell size because a floating gate type cell requires a high voltage in program/erase operations and it is difficult to obtain a margin in a process such as definition of a tunnel. Therefore, a research on a nonvolatile memory device such as a silicon-oxide-nitride-oxide-silicon (SONOS), a ferroelectric random access memory (FeRAM), a single electron transistor (SET), and a nitride read-only memory (NROM) has been conducted into ways of replacing the floating gate type cell. The SONOS cell has been in the limelight as a new generation cell replacing the floating gate type cell.

Meanwhile, a cell structure of the EEPROM may be mainly classified into an EEPROM tunnel oxide (ETOX) cell of a stack structure and a split gate type cell configured with two transistors per one cell.

In the ETOX cell, a floating gate storing charges and a control gate receiving a driving voltage are stacked to constitute a gate. On the other hand, in the split gate type cell, one memory cell is configured with two transistors: a selection transistor for selecting a cell and a memory transistor for storing data. The memory transistor includes a floating gate storing charges, a control gate electrode for controlling the memory transistor, and an intergate dielectric layer interposed therebetween.

Hereinafter, a related art nonvolatile memory device of a split gate type SONOS cell structure will be described with reference to the accompanying drawings.

FIGS. 1A and 1B are a photographic image and a cross-sectional view for illustrating a problem in fabrication of a related art nonvolatile memory device.

The related art nonvolatile memory device includes a cell region and a logic region. An isolation region and an active region are defined in each region, and a low voltage region and a high voltage region are defined in the logic region.

According to a method of fabricating the related art nonvolatile memory device, a shallow trench isolation (STI) region is formed in each isolation region of a substrate 30. An oxide-nitride-oxide (ONO) layer for trapping electrons is formed on an entire surface of the substrate 30. A first polysilicon layer is deposited thereon, and patterned to form a first gate electrode in the cell region. Oxide layers having different thicknesses are formed in the low voltage region and the high voltage region of the logic region, respectively. A second polysilicon layer is deposited on an entire surface of the substrate 30.

Next, the second polysilicon layer of the logic region is etched to form gate electrodes in the low and high voltage regions, respectively.

Next, the second polysilicon layer of the cell region is removed to form a second gate electrode.

Here, the removing of the second polysilicon layer is divided into three operations: masking the second polysilicon layer with a photoresist layer 36 and removing an oxide layer (not shown) formed thin on a surface of the second polysilicon layer; removing the second polysilicon layer; and exposing the substrate 30. Here, as illustrated in FIGS. 1A and 1B, a large thickness of the second polysilicon layer may cause hole damage of a surface of an adjacent STI region during etch of the second polysilicon layer.

The photoresist layer 36 is spaced a predetermined distance, e.g., approximately 0.1 μm from the second polysilicon layer, in order to prevent a problem that the second polysilicon layer is not etched.

As described above, when the gate of the logic region is formed, and then the second polysilicon layer of the cell region is etched to form the second gate electrode, a surface of the substrate 30 adjacent to the second gate electrode of the cell region, e.g., of the STI region receives hole damage, consequently decreasing the yield of the device.

### SUMMARY OF THE INVENTION

Accordingly, the present invention is directed to a method of fabricating a nonvolatile memory device that substantially obviates one or more problems due to limitations and disadvantages of the related art.

An object of the present invention is to provide a method of fabricating a nonvolatile memory device capable of preventing damage of a surface of a substrate, e.g., a shallow trench isolation (STI) region while forming a cell region and a logic region.

Additional advantages, objects, and features of the invention will be set forth in part in the description which follows and in part will become apparent to those skilled in the art upon examination of the following or may be learned from practice of the invention. The objectives and other advantages of the invention may be realized and attained by the structure(s) particularly pointed out in the written description and claims hereof as well as the appended drawings.

To achieve these objects and other advantages and in accordance with the purpose of the invention, as embodied and broadly described herein, there is provided a method of fabricating a nonvolatile memory device in a semiconductor substrate where a cell region and a logic region are defined, an isolation region and an active region are defined in each of the cell region and the logic region, and a low voltage region and a high voltage region are defined in the logic region, the method including: forming a shallow trench isolation region in the isolation region; forming a first gate insulating layer and a first gate electrode in one region of the cell region; forming second and third gate insulating layers in respective regions of the logic region; depositing a semiconductor layer on an entire surface of the semiconductor substrate; etching the semiconductor layer to form a second gate electrode to overlap a portion of the first gate electrode; coating an entire surface of the semiconductor substrate with a bottom antireflection coating layer; and etching the semiconductor layer to form third and fourth gate electrodes in respective regions of the logic region.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle(s) of the invention. In the drawings:

FIGS. 1A and 1B are a photographic image and a cross-sectional view for illustrating a problem in fabrication of a related art nonvolatile memory device, respectively;

FIG. 2 is a sectional view illustrating a structure of a nonvolatile memory device applied to the present invention;

FIGS. 3A to 3K are sectional views illustrating a method of fabricating a nonvolatile memory device according to an embodiment of the present invention; and

FIGS. 4A and 4B are enlarged views illustrating a nonvolatile memory device where a second polysilicon pattern of a cell region is formed prior to etching of a second polysilicon layer of a logic region, according to an embodiment of the present invention.

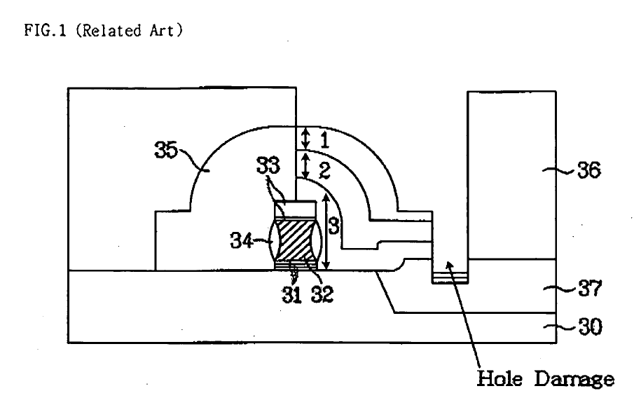

### DETAILED DESCRIPTION OF THE INVENTION

Hereinafter, a method of fabricating a nonvolatile memory device according to an embodiment of the present invention will be described with reference to the accompanying drawings.

It will be understood that when a layer is referred to as being “on” another layer, it can be directly on the other layer, or intervening layers may also be present.

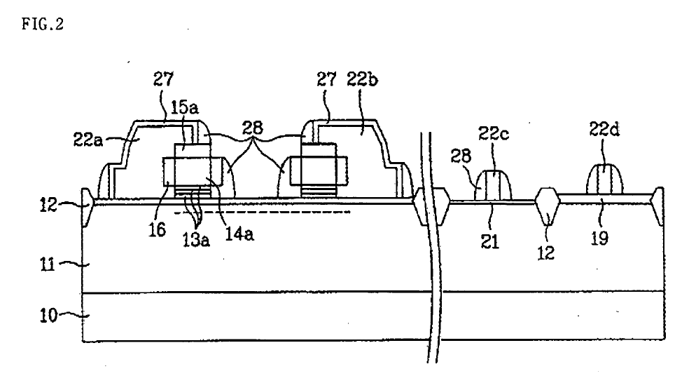

FIG. 2 is a sectional view illustrating a structure of a nonvolatile memory device applied to the present invention.

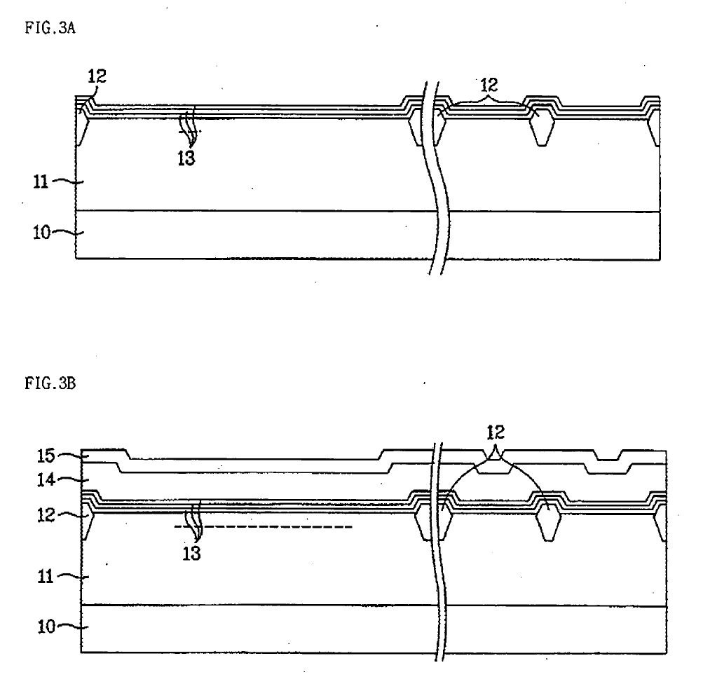

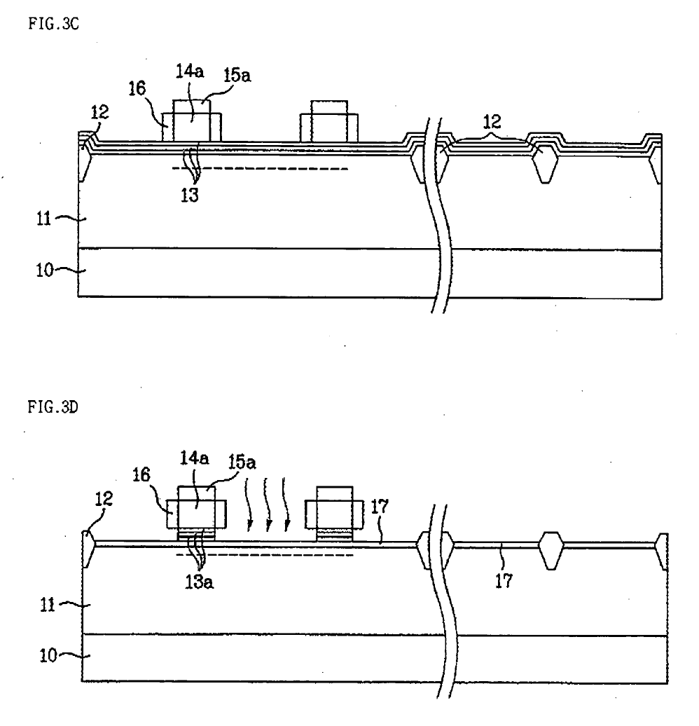

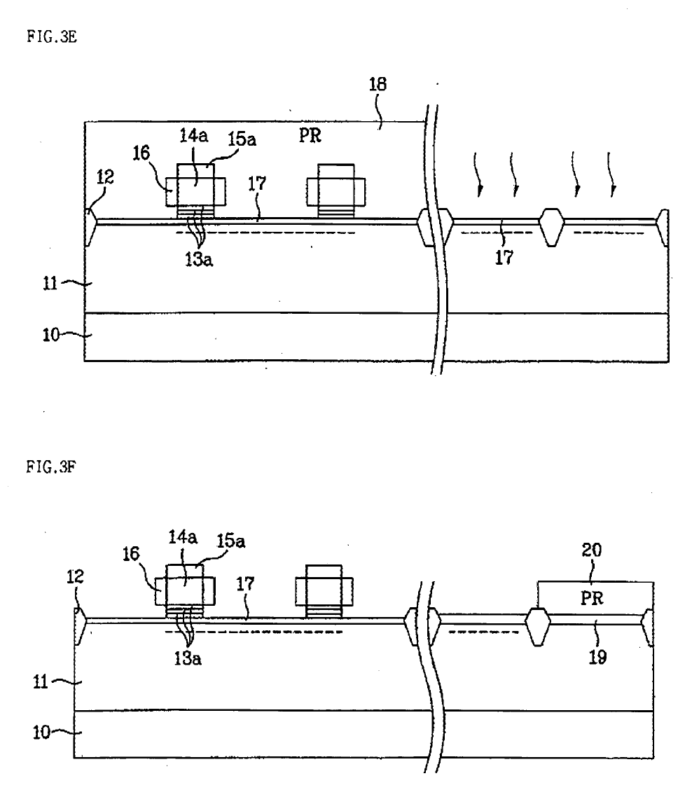

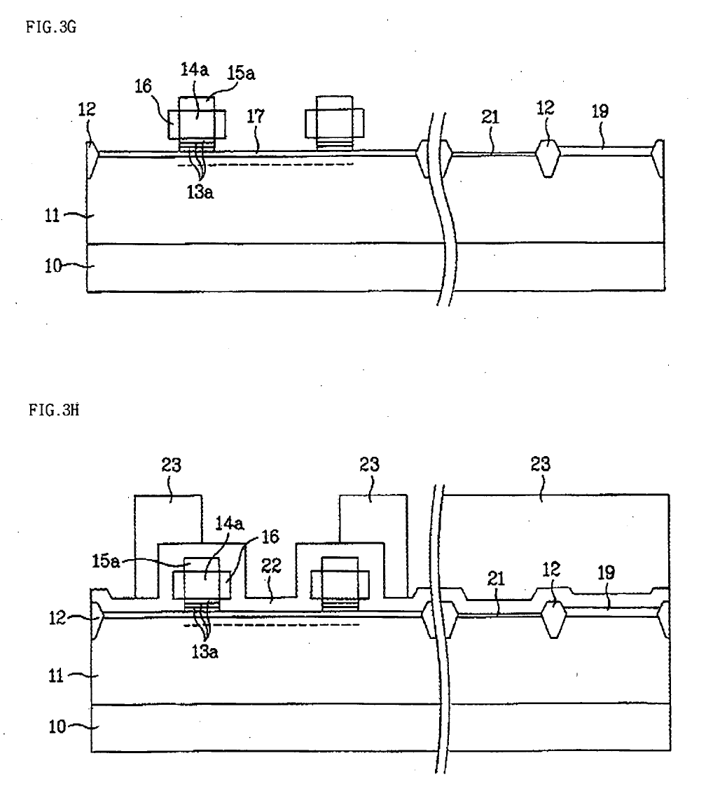

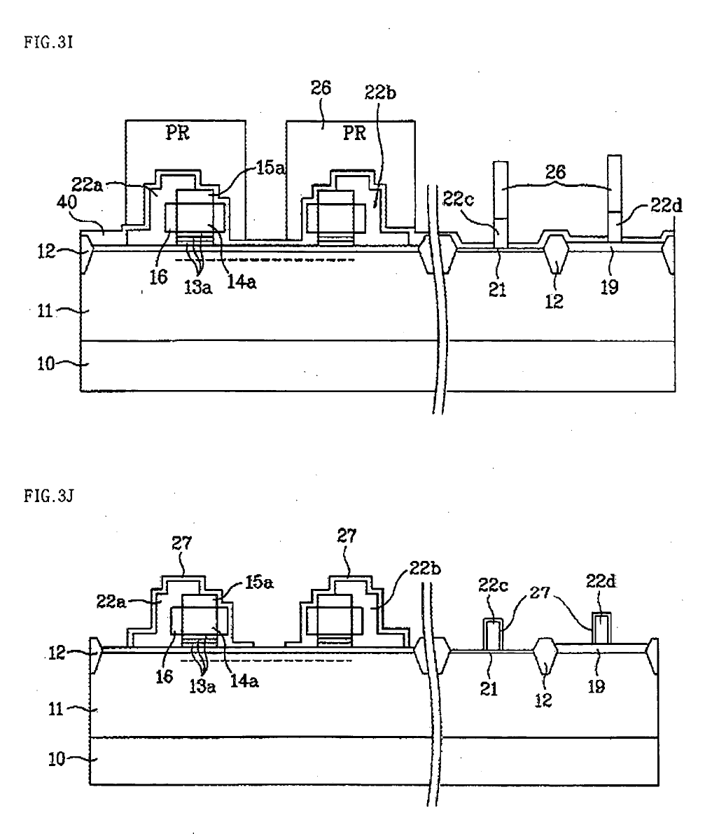

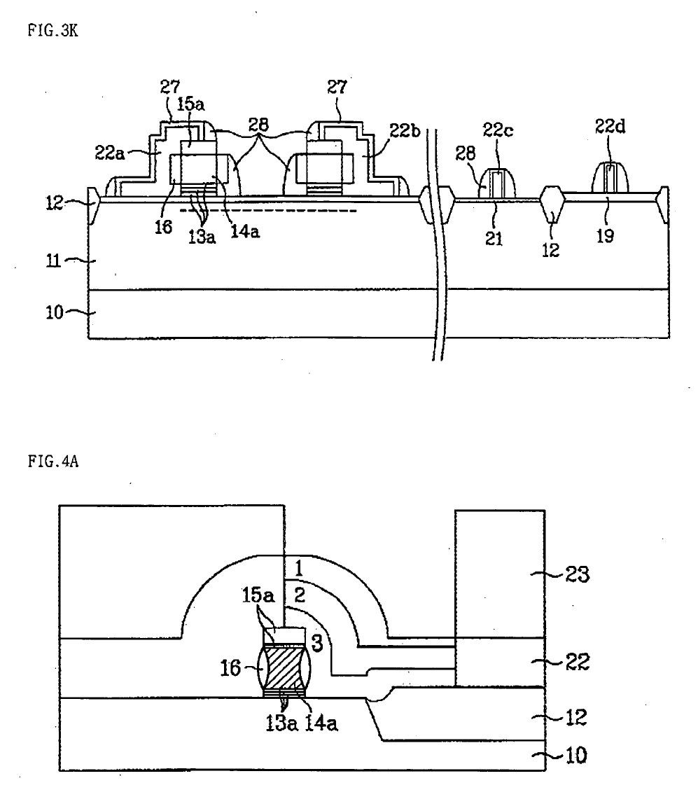

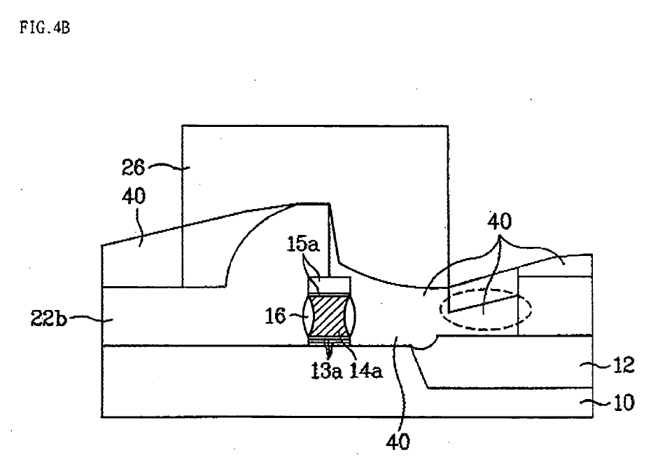

FIGS. 3A to 3K are sectional views illustrating a method of fabricating a nonvolatile memory device according to an embodiment of the present invention. FIGS. 4A and 4B are enlarged views illustrating a nonvolatile memory device where a second polysilicon of a cell region is patterned prior to etch of a second polysilicon layer of a logic region, according to an embodiment of the present invention.

According to the method of fabricating the nonvolatile memory device, referring to FIGS. 2 and 3A, a cell region and a logic region are defined in a semiconductor substrate 10, and an isolation region and an active region are defined in each of the cell region and the logic region. A shallow trench isolation (STI) region 12 is formed in each isolation region.

A low voltage region and a high voltage region are defined in the logic region.

Then, a first insulating layer 13 of an oxide-nitride-oxide (ONO) structure for trapping electrons is deposited on an entire surface of the semiconductor substrate 10.

Referring to FIG. 3B, a first polysilicon layer 14 is deposited on the first insulating layer 13.

Subsequently, ions are implanted into the first polysilicon layer 14, and then annealing is performed thereon.

Although not shown, a thin cap oxide layer may be further formed on the first polysilicon layer 14.

Next, a second insulating layer 15 is formed of a nitride layer on the first polysilicon layer 14 in order to isolate the first polysilicon layer 14 from a second polysilicon layer to be formed later.

Referring to FIG. 3C, the first polysilicon layer 14 and the second insulating layer 15 are etched using a photo mask to form a first gate electrode 14a and a first cap insulating layer 15a. An oxidation process is performed to cure damage caused by the etching, and thereby a first sidewall spacer 16 is formed on a side of the first gate electrode 14a.

Referring to FIG. 3D, in order to control a threshold voltage of a split gate SONOS device, and then threshold voltage ions are implanted into the first gate electrode 14a and a surface of the semiconductor substrate 10 adjacent to the first gate electrode 14a, with masking using a photo mask.

Next, an exposed portion of the first insulating layer 13 of an ONO structure on the semiconductor substrate 10 is removed. An UV oxidation process is performed to form a third insulating layer 17, in order to form a device for programming the split gate SONOS device.

Referring to FIG. 3E, after patterning the first gate electrode 14a of the cell region, a first photoresist layer 18 is patterned using a photo mask so as to mask the cell region, and then ions for forming a gate are implanted into the logic region.

Referring to FIG. 3F, a thick fourth insulating layer 19 is deposited in the logic region through a thermal oxidation process, and then patterned using a photo mask such that a second photoresist layer 20 masks a high voltage region. Consequently, a low voltage region of the logic region is exposed.

Referring to FIG. 3G, the fourth insulating layer 19 of the low voltage region is removed using the second photoresist layer 20 as a mask, and then a fifth insulating layer 21 having a thickness smaller than the thickness of the fourth insulating layer 19 is formed in the low voltage region through a thermal oxidation process.

The fourth insulating layer 19 is a gate insulating layer of the high voltage region, and the fifth insulating layer 21 is a gate insulating layer of the low voltage region.

Referring to FIGS. 3H and 4A, a second polysilicon layer 22 is deposited on an entire surface of the semiconductor substrate 10. Next, a third photoresist layer 23 is patterned using a photo mask such that only the entire logic region and a region for forming second gate electrodes 22a and 22b are masked.

Referring to FIGS. 3I and 4B, the second polysilicon layer 22 is etched using the patterned third photoresist layer 23 as a mask to form second gate electrodes 22a and 22b so as to partially overlap an upper portion of the first gate electrode 14a.

Before forming a gate of the logic region, a bottom antireflection coating (BARC) layer 40 is spin-coated on an entire surface of the semiconductor substrate 10. A fourth photoresist layer 26 is patterned on the antireflection layer 40 using a photo mask so as to selectively mask first and second gate regions of the cell region and a gate electrode forming region of the low and high voltage regions of the logic region.

Next, the second polysilicon layer 22 of the logic region is etched using the patterned fourth photoresist layer 26 as a mask to form third and fourth gate electrodes 22c and 22d in the low voltage region and the high voltage region, respectively.

As illustrated in FIGS. 4A and 4B, when the second polysilicon layer 22 of the cell region is etched to form the second gate electrodes 22a and 22b in the cell region, and then the gate of the logic region is formed, the BARC layer 40 coated on the entire semiconductor substrate 10 prior to the patterning of the gate of the logic region protects the top portion of the STI region 12 adjacent to the second gate electrodes 22a and 22b of the cell region. Therefore, when the gate of the logic region is patterned, the STI region of the cell region can be prevented from being damaged.

The BARC layer 40 is removed together when the fourth photoresist layer 26 is removed.

Referring to FIG. 3J, a sixth insulating layer 27 is deposited thin on surfaces of the first to fourth gate electrodes 22a, 22b, 22c and 22d of the cell region and the logic region.

Referring to FIG. 3K, the sixth insulating layer 27 is deposited and etched to form second sidewall spacers on sides of the first to fourth gate electrodes 22a, 22b, 22c and 22d.

A reference numeral 11 refers to a well region.

As described above, according to a method of fabricating a nonvolatile memory device of the present invention, a second gate electrode pattern of a cell region is formed prior to a gate electrode of a logic region. Therefore, a previously coated BARC layer can efficiently prevent a STI region of the cell region from being damaged while a gate of the logic region is formed.

It will be apparent to those skilled in the art that various modifications and variations can be made in the present invention. Thus, it is intended that the present invention covers the modifications and variations of this invention provided they come within the scope of the appended claims and their equivalents.

What is claimed is:

1. A method of fabricating a nonvolatile memory device in a semiconductor substrate having a cell region and a logic region, an isolation region and an active region in each of the cell region and the logic region, and a low voltage region and a high voltage region in the logic region, the method comprising:
forming a shallow trench isolation structure in each of the isolation regions;
forming a first gate insulating layer and a first gate electrode in the cell region;
forming second and third gate insulating layers in respective active regions of the logic region;
depositing a semiconductor layer on an entire surface of the semiconductor substrate;
etching the semiconductor layer to form a second gate electrode overlapping a portion of the first gate electrode;
coating an entire surface of the semiconductor substrate with a bottom antireflection coating layer; and
etching the semiconductor layer to form third and fourth gate electrodes in respective regions of the logic region.

2. The method according to claim 1, wherein the first gate insulating layer comprises an oxide-nitride-oxide structure.

3. The method according to claim 1, wherein forming the first gate electrode comprises:
depositing a first polysilicon layer and implanting ions into the first polysilicon layer;
forming an insulating layer on an entire surface of the semiconductor substrate including the first polysilicon layer; and
etching the first polysilicon layer and the insulating layer using a photo mask.

4. The method according to claim 1, further comprising performing an oxidation process to form a first sidewall spacer on a side of the first gate electrode.

5. The method according to claim 1, further comprising forming second sidewall spacers on sides of the first and second gate electrodes of the cell region.

6. The method according to claim 1, further comprising forming second sidewall spacers on sides of the third and fourth gate electrodes of the logic region.

7. The method according to claim 1, wherein the third gate insulating layer in the high voltage region is thicker than the second gate insulating layer in the low voltage region.

8. The method according to claim 1, wherein a plurality of first and second gate electrodes are formed in the cell area.

9. A method of fabricating a nonvolatile memory device, comprising:
forming a plurality of isolation regions in a semiconductor substrate, the isolation regions defining a cell region having an active area, a high voltage logic region, and a low voltage logic region;
forming a first gate insulating layer and a plurality of first gate electrodes in the active area of the cell region;
forming a second gate insulating layer in the low voltage logic region and a third gate insulating layer in the high voltage logic region, the third gate insulating layer having a greater thickness than the second gate insulating layer;
depositing a semiconductor layer on an entire surface of the semiconductor substrate;
etching a part of the semiconductor layer to form a second gate electrode overlapping a portion of the first gate electrode;
coating an entire surface of the semiconductor substrate with an antireflection coating layer; and
etching a remaining part of the semiconductor layer to form a third gate electrode in the high voltage logic region and a fourth gate electrode in the low voltage logic region.

10. The method according to claim 9, wherein the first gate insulating layer comprises an oxide-nitride-oxide structure.

11. The method according to claim 9, wherein forming the first gate electrode comprises:
depositing a first polysilicon layer and implanting ions into the first polysilicon layer;
forming an insulating layer on an entire surface of the semiconductor substrate including the first polysilicon layer; and
etching the first polysilicon layer and the insulating layer using a first photo mask.

12. The method according to claim 9, further comprising oxidizing a side of the first gate electrode to form a first sidewall spacer.

13. The method according to claim 9, further comprising forming second sidewall spacers on sides of the first and second gate electrodes.

14. The method according to claim 13, wherein forming the second sidewall spacers further forms second sidewall spacers on sides of the third and fourth gate electrodes.

15. The method according to claim 9, further comprising forming second sidewall spacers on sides of the third and fourth gate electrodes.

16. The method according to claim 9, further comprising forming a second photo mask on the semiconductor layer prior to forming the second gate electrodes.

17. The method according to claim 16, wherein the second photo mask remains over the high and low voltage logic regions when the semiconductor layer is etched to form the second gate electrodes.

18. The method according to claim 16, further comprising forming a third photo mask over the remaining part of the semiconductor layer prior to forming the third and fourth gate electrodes.

19. The method according to claim 18, wherein the third photo mask remains over the second gate electrodes and a part of the antireflection coating layer in the cell region when the semiconductor layer is etched to form the third and fourth gate electrodes.
